(19) United States
(12) Patent Application Publication
(10) Pub. No.: US 2024/0336400 A1
(43) Pub. Date: Oct. 10, 2024

(54) TRAY MODULE

(71) Applicant: SAMSUNG DISPLAY CO., LTD., YONGIN-SI (KR)

(72) Inventors: MIN-YEOB KANG, YONGIN-SI (KR); SANGWOO KIM, YONGIN-SI (KR); NAMPYO HONG, YONGIN-SI (KR)

(21) Appl. No.: 18/601,823

(22) Filed: Mar. 11, 2024

(30) Foreign Application Priority Data
Apr. 5, 2023 (KR) 10-2023-0044944

(51) Int. Cl. B65D 25/10; B65D 1/34; B65D 81/05; B65D 85/48

(52) U.S. Cl. CPC B65D 25/10; B65D 1/34; B65D 81/05; B65D 85/48

(57) ABSTRACT

A tray module includes a tray and a pad. The pad is disposed on the tray. The pad includes a plurality of flow prevention patterns formed thereon that have a square shape in a plan view and protrude in a cross-sectional view.

### CROSS-REFERENCE TO RELATED APPLICATION

This application claims priority under 35 U.S.C. § 119 from Korean Patent Application No. 10-2023-0044944, filed on Apr. 5, 2023 in the Korean Intellectual Property Office, the contents of which are herein incorporated by reference in their entirety.

### TECHNICAL FIELD

Embodiments of the disclosure are directed to a tray module. More specifically, embodiments of the disclosure are directed to a tray module that can transport a display device.

### DISCUSSION

A seating area in which a transport object, such as a display device, can be placed may be defined on a tray. The transport object is transported and stored while seated on the tray to prevent damage to the transport object during a manufacturing process.

### SUMMARY

Embodiments of the disclosure provide a tray module.

A tray module includes a tray, and a pad disposed on the tray, where the pad has a square shape in a plan view, and includes a plurality of flow prevention patterns that protrude in a cross-section view.

In an embodiment, a distance between each of the plurality of flow prevention patterns is constant.

In an embodiment, the distance between each of the plurality of flow prevention patterns is greater than or equal to about 3 mm and less than or equal to about 5 mm. In an embodiment, each of the plurality of flow prevention patterns has a same

width.

In an embodiment, the distance between each of the plurality of flow prevention patterns and the width of each of the plurality of flow prevention patterns is a same.

In an embodiment, the width of each of the plurality of flow prevention patterns is greater than or equal to about 3 mm and less than or equal to about 5 mm.

In an embodiment, a height of each of the plurality of flow prevention patterns are equal to each other.

In an embodiment, the height of each of the plurality of flow prevention patterns is greater than or equal to about 0.15 mm and less than or equal to about 0.25 mm.

In an embodiment, the tray includes a protruding portion that protrudes in a direction parallel to a protruding direction of the plurality of flow prevention patterns, and a hole formed at a position that corresponds to a position of the protruding portion.

In an embodiment, the pad includes an elastomer.

A tray module includes a bottom portion, a plurality of flow prevention patterns that protrude from the bottom portion in a cross-sectional view and have a square shape in a plan view, and a wall portion that extends in a direction upward from the bottom portion in a cross-sectional view and surrounds the bottom portion in a plan view.

In an embodiment, a distance between each of the plurality of flow prevention patterns is constant.

In an embodiment, the distance between each of the plurality of flow prevention patterns is greater than or equal to about 3 mm and less than or equal to about 5 mm.

In an embodiment, each of the plurality of flow prevention patterns has a same width.

In an embodiment, the distance between each of the plurality of flow prevention patterns and the width of each of the plurality of flow prevention patterns are a same.

In an embodiment, the width of each of the plurality of flow prevention patterns is greater than or equal to about 3 mm and less than or equal to about 5 mm.

In an embodiment, a height of each of the plurality of flow prevention patterns are equal to each other.

In an embodiment, the height of each of the plurality of flow prevention patterns is greater than or equal to about 0.15 mm and less than or equal to about 0.25 mm.

In an embodiment, each of the bottom portion, the plurality of flow prevention patterns, and the wall portion includes an elastomer.

In an embodiment, each of the bottom portion, the plurality of flow prevention patterns, and the wall portion are integrally formed.

A tray module according to an embodiment of the disclosure includes a tray, and a pad disposed on the tray that has a square shape in a plan view, and the pad includes a plurality of flow prevention patterns that protrude in a cross-section view. Accordingly, bidirectional flow of a loading target part on the pad is prevented during transportation and the loading target part is easily adhered to and detached from the pad.

A tray module according to an embodiment of the disclosure includes a bottom portion, a plurality of flow prevention patterns that protrude from the bottom portion in a cross-sectional view and have a square shape in a plan view, and a wall portion that extends in a direction upward from the bottom portion in a cross-sectional view and surrounds the bottom portion in a plan view. Accordingly, bidirectional flow of a loading target part on the bottom portion can be prevented during transportation and the loading target part is easily adhered to and detached from the tray.

### BRIEF DESCRIPTION OF THE DRAWINGS

FIG. 1 is a perspective view of a tray module according to an embodiment of the disclosure.

FIG. 2 is a cross-sectional view of a tray in a tray module of FIG. 1.

FIG. 3 is a cross-sectional view taken along line I-I′ of FIG. 1.

FIG. 4 is a perspective view of a pad in a tray module of FIG. 1.

FIG. 5 is a plan view of a pad of FIG. 4.

FIGS. 6 and 7 illustrate a method of transporting a loading target part using a tray module of FIG. 1.

FIG. 8 illustrates a method of transporting a plurality of tray modules of FIG. 1.

FIG. 9 is a perspective view of a tray module according to an embodiment of the disclosure.

FIG. 10 is a cross-sectional view taken along line III-III' of FIG. 9.

FIG. 11 is a perspective view of a tray in a tray module of FIG. 9.

FIGS. 12 and 13 illustrate a method of transporting a loading target part using a tray module of FIG. 9.

FIG. 14 illustrates a method of transporting a plurality of tray modules of FIG. 9.

### DETAILED DESCRIPTION

Embodiments of the present disclosure will be more clearly understood from the following detailed description in conjunction with the accompanying drawings.

The term “about” as used herein is inclusive of the stated value and means within an acceptable range of deviation for the particular value as determined by one of ordinary skill in the art, considering the measurement in question and the error associated with measurement of the particular quantity, such as the limitations of the measurement system. For example, “about” may mean within one or more standard deviations as understood by one of the ordinary skill in the art. Further, it is to be understood that while parameters may be described herein as having “about” a certain value, according to embodiments, the parameter may be exactly the certain value or approximately the certain value within a measurement error as would be understood by a person having ordinary skill in the art.

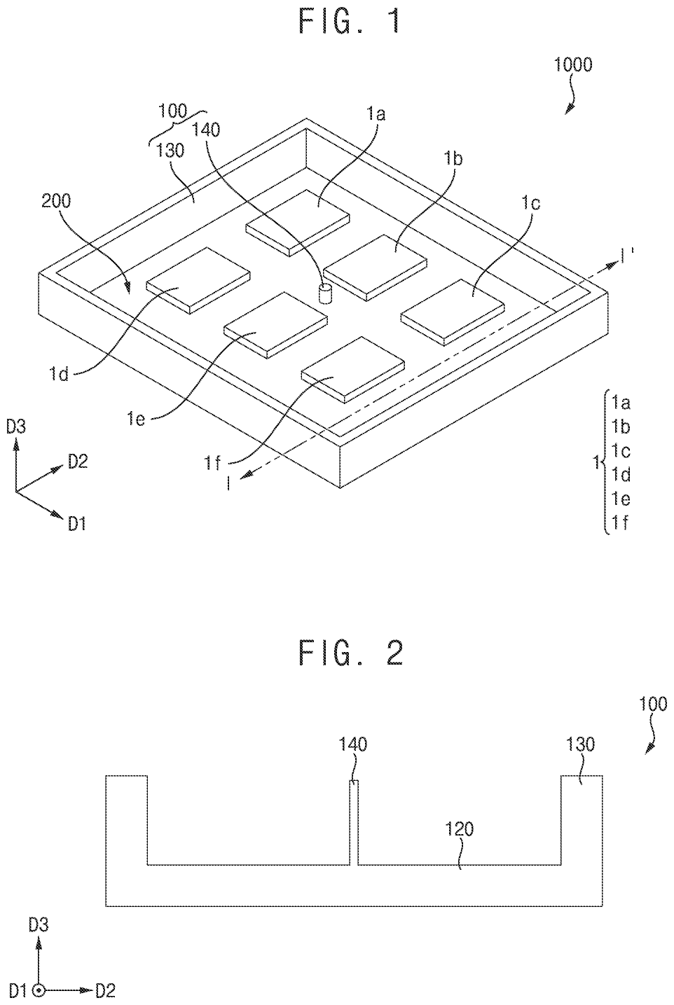

FIG. 1 is a perspective view of a tray module according to an embodiment of the disclosure.

Referring to FIG. 1, a tray module 1000 according to an embodiment of the disclosure includes a tray 100 and a pad 200. The tray module 1000 can accommodate a loading target part 1. For example, the loading target part 1 can be seated on the pad 200.

The tray 100 includes a material that can be injection molded. For example, the tray 100 includes at least one of acrylonitrile-butadiene styrene (ABS), polyethylene terephthalate (PET), polycarbonate (PC), polypropylene (PP) and polyolefin resin, high density polyethylene (HDPE), or thermoplastic polyolefin (TPO), etc. These can be used alone or in combination with each other.

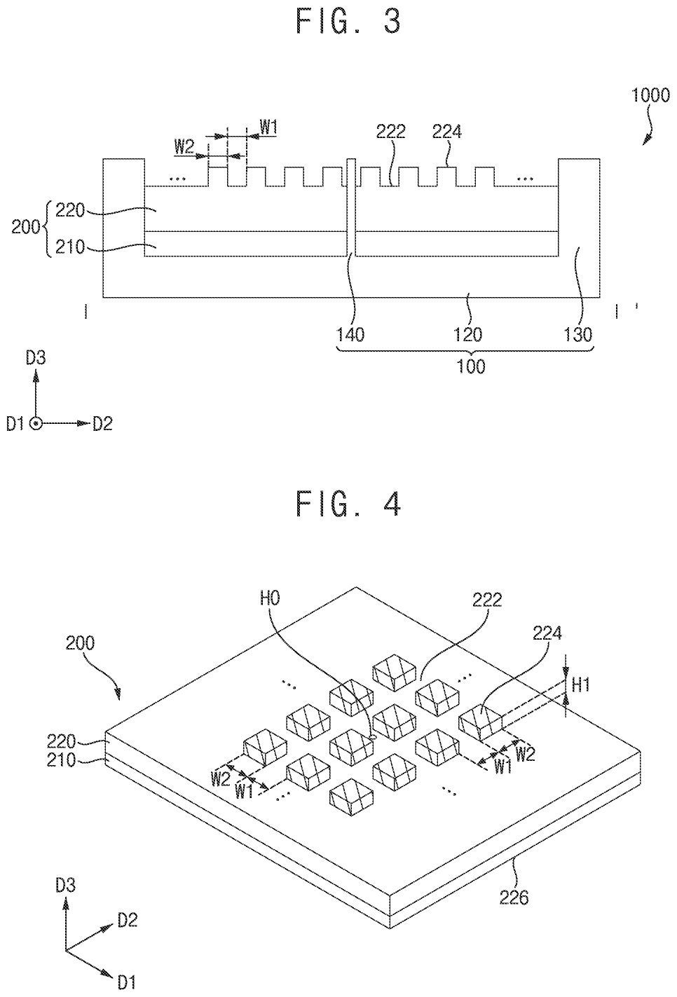

The pad 200 includes a non-slip material. In an embodiment, the pad 200 includes an elastomer. Accordingly, the loading target part 1 disposed on the pad 200 can be prevented from slipping in a first direction D1 and/or a second direction D2. For example, the pad 200 includes a high frictional force material that prevents the loading target part 1 from moving during transportation. A detailed description of the elastomer included in the pad 200 will be described below with reference to FIGS. 3 to 5.

The second direction D2 crosses the first direction D1. For example, the first direction D1 and the second direction D2 are perpendicular to each other.

The tray module 1000 can accommodate a plurality of the loading target parts 1. For example, the tray module 1000 can accommodate a first loading target part 1a, a second loading target part 1b, a third loading target part 1c, a fourth loading target part 1d, a fifth loading target part, and a sixth loading target part 1f.

Each of the first loading target part 1a, the second loading target part 1b, the third loading target part 1c, the fourth loading target part 1d, the fifth loading target part, and the sixth loading target part 1f is accommodated in the tray module 1000 and spaced apart from each other. For example, each of the first loading target part 1a, the second loading target part 1b, the third loading target part 1c, the fourth loading target part 1d, the fifth loading target part, and the sixth loading target part If is seated on the pad 200 and spaced apart from each other.

FIG. 1 shows that the number of the loading target parts 1 s 6, however, this is for convenience of illustration and embodiments of the disclosure are not necessarily limited thereto. For example, n pieces of the loading target parts can be accommodated in the tray module 1000. The number n is a natural number of 1 or more. Alternatively, the loading target part 1 might not be accommodated in a tray module 1000. For example, when the tray module 1000 includes a plurality of multi-stacked trays 100, the loading target part 1 might not be disposed on an uppermost tray.

The loading target part 1 may be a substrate, an electronic device, a display device, etc.

For example, the substrate is rigid. For example, the substrate includes a glass, etc. For another example, the substrate is flexible. For example, the substrate includes polyimide, etc.

For example, the electronic device is one of a driving chip, a circuit board, etc., disposed on the substrate.

For example, the display device is one of an organic light emitting display device, a micro LED display device, a nano LED display device, a quantum dot light emitting display device, a liquid crystal display device, a plasma display device, a field emission display device, an electrophoretic display device, or an electrowetting display device, etc.

FIG. 1 shows that a seating surface of the loading target part 1, such as a surface in contact with the tray module 1000, is flat, however, this is for convenience of illustration and embodiments of the disclosure are not necessarily limited thereto. For example, the seating surface of the loading target part 1 can be curved. For example, the loading target part 1 is a curved panel, etc.

However, embodiments of the disclosure are not necessarily limited thereto. For example, the loading target part 1 is a part to be transported in a manufacturing process of a display device, a finished product, etc.

In FIG. 1, for convenience of illustration, a plurality of flow prevention patterns formed in the pad 200, such as a plurality of flow prevention patterns 224 of FIG. 2, are omitted. A detailed description of the plurality of flow prevention patterns will be described below with reference to FIG. 2, et seq.

FIG. 2 is a cross-sectional view of a tray in the tray module of FIG. 1.

Referring to FIGS. 1 and 2, in an embodiment, the tray 100 includes a bottom portion 120, a wall portion 130, and a protruding portion 140.

The bottom portion 120 provides a surface on which the pad 200 is seated. For example, the pad 200 is disposed on the bottom portion 120. For example, the bottom portion 120 extends in the first direction D1 and the second direction D2.

The wall portion 130 surrounds the bottom portion 120 in a plan view and extends or protrudes in a direction upward from the bottom portion 120 in a cross-sectional view.

A portion of the wall portion 130 extends in the first direction D1 and a third direction D3. In addition, another portion of the wall portion 130 extends in the second direction D2 and the third direction D3. For example, the third direction D3 crosses each of the first direction D1 and the second direction D2. For example, each of the first direction D1, the second direction D2, and the third direction D3 are mutually perpendicular.

In an embodiment, the protruding portion 140 is disposed in the tray 100. The protruding portion 140 extends in a direction parallel to an extension direction of the wall portion 130 with respect to the bottom portion 120, or in a direction parallel to a protrusion direction of the plurality of flow prevention patterns 224, such as the third direction D3.

However, embodiments of the disclosure are not necessarily limited thereto. In embodiments, the tray 100 has various shapes. For example, in some embodiments, the tray 100 does not include the protruding portion 140.

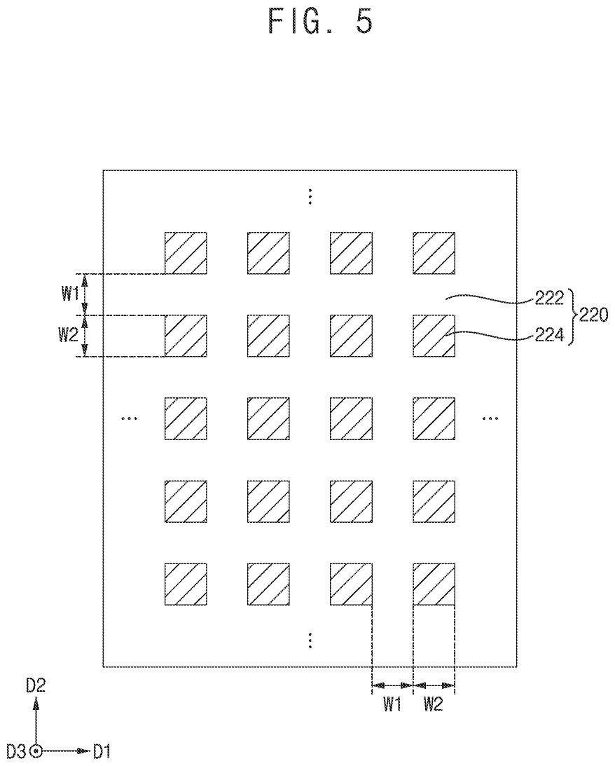

FIG. 3 is a cross-sectional view taken along the line I-I′ of FIG. 1. FIG. 4 is a perspective view of a pad in the tray module of FIG. 1. FIG. 5 is a plan view of the pad of FIG. 4.

Referring to FIGS. 1, 2, 3, 4, and 5, in an embodiment, the pad 200 is disposed on the tray 100. The pad 200 can be attached to or detached from the tray 100.

In an embodiment, a hole HO is further formed in the pad 200 at a position that corresponds to where the protruding portion 140 is disposed. The protruding portion 140 can be fitted into the hole HO formed in the pad 200. Accordingly, the pad 200 is fixed to the tray 100. However, embodiments of the disclosure are not necessarily limited thereto. For example, the pad 200 can be fixed to the tray 100 in various other ways.

In an embodiment, the pad 200 includes a top surface 222 and a bottom surface 226. The bottom surface 226 faces the top surface 222. For example, the bottom surface 226 and the top surface 222 face each other in the third direction D3.

In an embodiment, the pad 200 has a multi-layer structure. For example, the pad 200 includes a base portion 210 and a pattern portion 220. For example, the top surface 222 of the pad 200 is the top surface of the pattern portion 220, and the bottom surface 226 of the pad 200 is the bottom surface of the base portion 210.

The base portion 210 supports the pattern portion 220. For example, the base portion 210 is positioned on the tray 100 and the pattern portion 220 is positioned on the base portion 210.

In an embodiment, the base portion 210 includes a thermoplastic polymer resin. For example, the thermoplastic polymer resin is one or more of polyester (PET A, PET G, PET G-PET A-PET G), styrene butadiene copolymer (SBC), acrylonitrile-butadiene styrene (ABS), polystyrene (PS), polyimide (PI), polyamide, polysulfonate, polycarbonate, polyacrylate, polyvinyl chloride (PVC), polyethylene (PE), polypropylene (PP), modified polyphenylene oxide (M-PPO), blends or copolymers thereof, phenol resin, epoxy resin, or urethane resin, etc. These can be used alone or in combination with each other.

However, embodiments of the disclosure are not necessarily limited thereto. For example, in some embodiments, the base portion 210 includes various other materials that can support the pattern portion 220. Alternatively, in an embodiment, the base portion 210 is omitted.

In an embodiment, the pattern portion 220 includes the plurality of flow prevention patterns 224. In an embodiment, each of the plurality of flow prevention patterns 224 has a square shape in a plan view and protrudes from the top surface 222 of the pad 200 in the cross-sectional view. Hereinafter, the top surface 222 of the pad 200 refers to a portion where the plurality of flow prevention patterns 224 are not formed.

For example, a plane is defined by the first direction D1 and the second direction D2. On the other hand, a cross section can be defined by the second direction D2 and the third direction D3. In addition, the cross section can be defined by the first direction D1 and the third direction D3. For example, each of the plurality of flow prevention patterns 224 protrudes from the top surface 222 of the pad 200 in the third direction D3.

In an embodiment, the pattern portion 220 includes a thermoplastic elastomer (TPE). A thermoplastic elastomer can be molded like a plastic that becomes flexible at high temperatures, and is a polymer material that exhibits elastomer properties at room temperature. The thermoplastic elastomer partially changes into hard parts and soft parts through use of processing equipment such as injection molding, so that product production can be diversified, and part design can be facilitated. The thermoplastic elastomer is elastic under use conditions, and can be molded like the thermoplastic under molding conditions.

For example, the thermoplastic elastomer includes at least one of a thermoplastic styrene block copolymer (SBC), a thermoplastic olefin elastomer (TPO), a thermoplastic polyurethane (TPU), a thermoplastic polyamide (TPAE), or a thermoplastic polyester elastomer (TPEE), etc. An olefin-based thermoplastic elastomer includes at least one of polypropylene (PP), polystyrene (PS), polyethylene (PE), nylon, styrene-acrylonitrile, ethylene propylene rubber (EPDM), natural rubber, styrene-butadiene rubber (SBR), ethylene vinyl acetate copolymer (EVA), or a glycol-modified polyethylene terephthalate (PET-G), etc.

However, embodiments of the disclosure are not necessarily limited thereto. For example, in some embodiments, the pattern portion 220 includes various other elastic materials.

FIGS. 3 and 4 show that the pad 200 has a multi-layer structure, however, embodiments of the disclosure are not necessarily limited thereto. Alternatively, in an embodiment, the pad 200 has a single-layer structure. For example, the pad 200 includes only the pattern portion 220.

Since the plurality of flow prevention patterns 224 include an elastomer, they are adhesive. When an adhesive force of the plurality of flow prevention patterns 224 is small, the loading target part 1 can be easily moved. When the adhesive force of the plurality of flow prevention patterns 224 is large, the loading target part 1 can be detached or attached.

In an embodiment, a distance W1 between the plurality of flow prevention patterns 224 is constant. In an embodiment, the distance W1 between the plurality of flow prevention patterns 224 is about 3 mm or more.

When the distance W1 between the plurality of flow prevention patterns 224 is less than about 3 mm, the loading target part 1 can move in the first direction D1 and/or the second direction D2 when the loading target part 1 disposed on the plurality of flow prevention patterns 224 is moved in the third direction D3. For example, when the distance W1 between the plurality of flow prevention patterns 224 is less than about 3 mm, the adhesive force is insufficient to prevent a vertical and horizontal movement of the loading target part 1, such as in the first direction D1 and/or the second direction D2.

On the other hand, when the distance W1 between the plurality of movement prevention patterns 224 is large, the loading target part 1 can move. For example, when the distance W1 between the plurality of flow prevention patterns 224 exceeds about 5 mm, the adhesive force is insufficient to prevent the vertical and horizontal movement of the loading target part 1.

In an embodiment, the plurality of flow prevention patterns 224 have a same width W2 as each other in the first direction D1 and the second direction D2. In an embodiment, the width W2 of each of the plurality of flow prevention patterns 224 is greater than or equal to about 3 mm and less than or equal to about 5 mm.

When the width W2 of each of the plurality of flow prevention patterns 224 is less than about 3 mm, the loading target part 1 can move in the first direction D1 and/or the second direction D2 when the loading target part 1 disposed on the plurality of flow prevention patterns 224 moves in the third direction D3. For example, when the width W2 of each of the plurality of flow prevention patterns 224 is less than about 3 mm, the adhesive force is insufficient to prevent the vertical and horizontal movement of the loading target part 1.

On the other hand, when the width W2 of each of the plurality of prevention patterns 224 is large, the loading target part 1 can move. For example, the width W2 of each of the plurality of flow prevention patterns 224 is about 5 mm or less. When the width W2 of each of the plurality of flow prevention patterns 224 exceeds about 5 mm, the adhesive force is insufficient to prevent the vertical and horizontal movement of the loading target part 1.

In an embodiment, the distance W1 between the plurality of flow prevention patterns 224 and the width W2 of each of the plurality of flow prevention patterns 224 are equal to each other.

An edge of the loading target part 1 can be caught in a groove formed by the plurality of flow prevention patterns 224. If a height of the plurality of flow prevention patterns 224 is too low, the edge of the loading target part 1 can easily escape from the groove.

In an embodiment, a height H1 of each of the plurality of flow prevention patterns 224 is the same as each other. In an embodiment, the height H1 of each of the plurality of flow prevention patterns 224 is greater than or equal to about 0.15 mm and less than or equal to about 0.25 mm.

When the height H1 of each of the plurality of flow prevention patterns 224 is less than about 0.15 mm, the loading target part 1 can move in the first direction D1 and/or the second direction D2 when the loading target part 1 disposed on the plurality of flow prevention patterns 224 is moved in the third direction D3. For example, when the height H1 of each of the plurality of flow prevention patterns 224 is less than about 3 mm, an amount of engagement is insufficient to prevent the vertical and horizontal movement of the loading target part 1.

On the other hand, when the height H1 of each of the plurality of flow prevention patterns 224 exceeds about 0.25 mm, the thickness of the pad 200 increases. Accordingly, a manufacturing cost of the pad 200 increases.

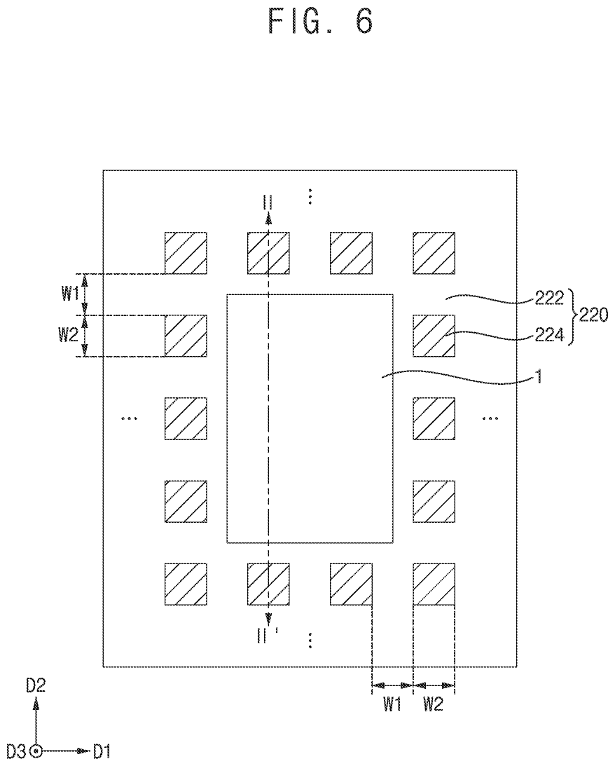

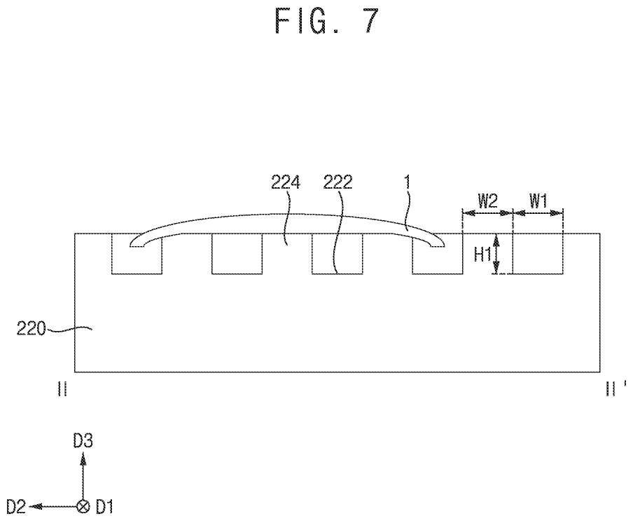

FIGS. 6 and 7 illustrate a method of transporting a loading target part using a tray module of FIG. 1.

For example, FIG. 6 is a plan view of the tray module 1000 of FIG. 1 and the loading target part 1 accommodated in the tray module 1000. FIG. 7 is a cross-sectional view taken along line II-II' of FIG. 6.

Referring to FIGS. 1, 6, and 7, in an embodiment, the plurality of flow prevention patterns 224 prevent the vertical and horizontal movement of the loading target part 1.

The loading target part 1 is disposed on the pad 200. When the number of the loading target part is plural, the loading target parts are spaced apart from each other as shown in FIG. 1. The loading target part 1 is disposed so that the edge of the loading target part 1 is disposed in the groove between the plurality of flow prevention patterns 224.

As described above, the pad 200 includes an elastomer. The elastomer is adhesive and non-slip. Accordingly, at a position where the loading target part 1 disposed on the pad 200 overlaps the plurality of flow prevention patterns 224, the plurality of flow prevention patterns 224 attach to the loading target part 1. At a position where the loading target part 1 disposed on the pad 200 does not overlap with the plurality of flow prevention patterns 224, such as a position of the top surface 222 of the pad 200, the edge of the loading target part 1 is caught in the groove between the plurality of flow prevention patterns 224 to prevent vertical and horizontal movement.

For example, the tray module 1000 does not include a pocket portion. A pocket portion is a portion where the loading target part 1 can be seated. Since the tray module 1000 does not include a pocket portion, the tray module 1000 can correspond to loading target parts 1 that have various sizes. For example, the tray module 1000 according to an embodiment of the disclosure can accommodate loading target parts 1 that have various sizes.

On the other hand, since the tray module 1000 includes an elastomer, the loading target part 1 can separate more easily from the tray module 1000 than when the tray module 1000 includes a high adhesive force material.

The plurality of flow prevention patterns 224 are disposed on the pad 200. The plurality of flow prevention patterns 224 have a square planar shape. The plurality of flow prevention patterns 224 have the same width W2 and are separated by a constant distance W1. Accordingly, the plurality of flow prevention patterns 224 provide the adhesive force and the amount of engagement is sufficient to prevent the vertical and horizontal movement of the loading target part 1. For example, the edge of the loading target part 1 is engaged between the plurality of flow prevention patterns 224 so that the vertical and horizontal movement is prevented.

A tray module according to a comparative embodiment includes a flow prevention pattern that have various shapes other than a square, such as a straight line shape, a rectangular shape, etc. For example, a tray module according to a comparative embodiment has decreased adhesion of the loading target part las compared to the tray module 1000 according to an embodiment of the disclosure, and does not prevent movement of the loading target part 1. Accordingly, the loading target part 1 accommodated in the tray module according to a comparative embodiment can easily move.

However, the tray module 1000 according to an embodiment of the disclosure can prevent the vertical and horizontal movement of the loading target part 1. When the tray module 1000 does not include the pocket portion, the loading target part 1 can move vertically and horizontally. However, the tray module 1000 according to an embodiment of the disclosure includes the plurality of flow prevention patterns 224 to prevent the vertical and horizontal movement of the loading target part 1. The plurality of flow prevention patterns 224 provide an adhesive force and increase the amount of engagement.

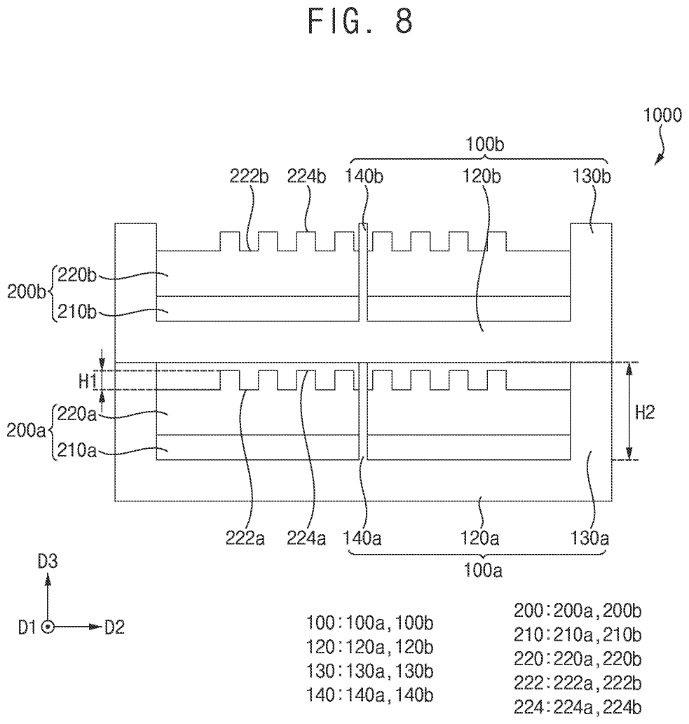

FIG. 8 illustrates a method of transporting a plurality of tray modules of FIG. 1.

Referring to FIG. 8, in an embodiment, the tray module 1000 includes at least one tray 100 and the pad 200. For example, the tray 100 includes a first tray 100a and a second tray 100b. The pad 200 includes a first pad 200a and a second pad 200b.

In an embodiment, the tray 100 includes the bottom portion 120, the wall portion 130, and the protruding portion 140. For example, the first tray 100a includes a first bottom portion 120a, a first wall portion 130a, and a first protrusion portion 140a. The second tray 100bincludes a second bottom portion 120b, a second wall portion 130b, and a second protrusion portion 140b.

In an embodiment, the first pad 200a is disposed on the first tray 100a, the second tray 100b is disposed on the first tray 100a and the first pad 200a, and the second pad 200b is disposed on the second tray 100b. For example, the first tray 100a, the first pad 200a, the second tray 100b, and the second pad 200b are sequentially stacked along the third direction D3.

A level of the top surface of the wall portion 130 is coplanar with the top surface of the protruding portion 140. The protruding portion 140 prevents sagging of a central portion of the multi-stacked tray 100, and the wall portion 130 prevents sagging of an edge portion of the multi-stacked tray 100. In a plan view, the edge portion surrounds the central portion. For example, the second tray 100b is supported by the first wall portion 130a and the first protrusion portion 140a of the first tray 100a.

In an embodiment, the pad 200 includes the base portion 210 and the pattern portion 220. For example, the first pad 200a includes a first base portion 210a and a first pattern portion 220a. The second pad 200b includes a second base portion 210b and a second pattern portion 220b.

In an embodiment, the pattern portion 220 include the plurality of flow prevention patterns 224 that protrude from the top surface 222 of the pad 200. For example, the first pattern portion 220a includes a plurality of first flow prevention patterns 224a that protrude from a top surface 222a of the first pad 200a. The second pattern portion 220b includes a plurality of second flow prevention patterns 224b that protrude from a top surface 222b of the second pad 200b.

In an embodiment, a height H2 of the protrusion portion 140 differs from the height H1 of each of the plurality of flow prevention patterns 224. For example, the height H2 of the protrusion portion 140 is greater than the height H1 of each of the plurality of flow prevention patterns 224. Accordingly, even if the loading target part 1 disposed on the first tray 100a moves in the third direction D3, breakage of the loading target part 1 due to a collision can be prevented.

As described above, the tray module 1000 according to an embodiment of the disclosure includes the tray 100 and the pad 200 disposed on the tray 100, where the pad 200 has a square shape in a plan view and includes an elastomer and the plurality of flow prevention patterns 224 that protrude in a cross-sectional view. Accordingly, it is possible to prevent bidirectional flow of the loading target part 1 seated on the pad 200 during transportation, and the loading target part 1 is easily adhered to and detached from the pad 200.

A static friction coefficient and a kinetic friction coefficient of the tray module 1000 according to an embodiment of the disclosure were measured using an ASTM D1894 method. As a result, the static friction coefficient of the tray module 1000 was about 4.92, and the kinetic friction coefficient was about 3.0. Accordingly, the tray module 1000 can prevent the loading target part 1 from slipping.

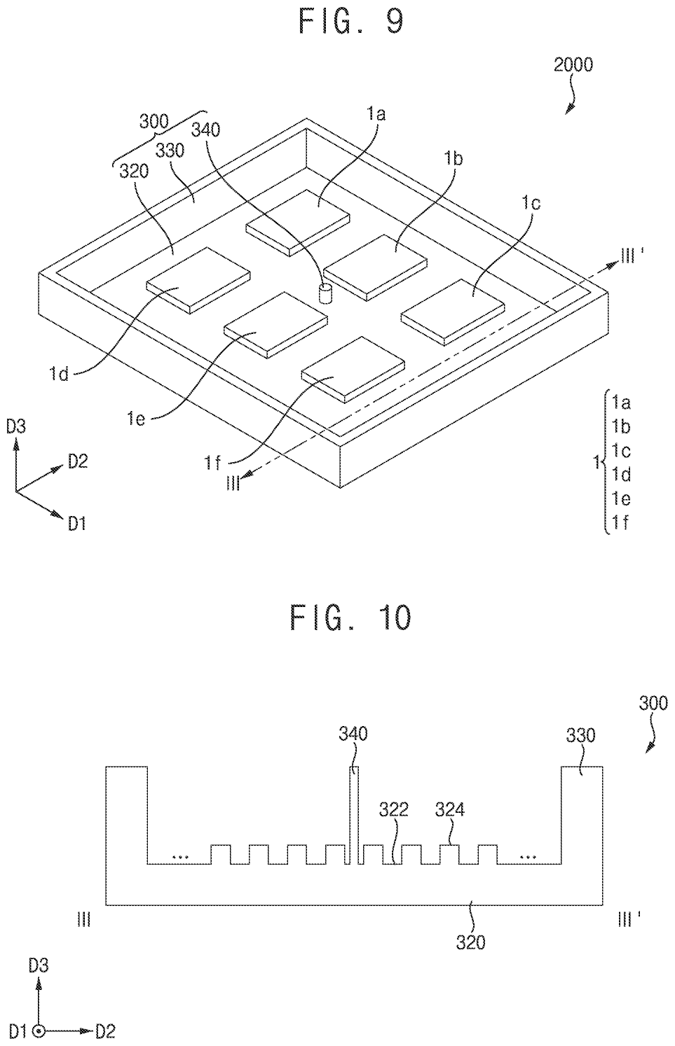

FIG. 9 is a perspective view of a tray module according to an embodiment of the disclosure.

A tray module 2000 of FIG. 9 includes a tray 300 that includes an elastomer, but does not include the pad, such as the pad 200 of FIG. 1. Hereinafter, descriptions that repeat those of the tray module 1000 described above with reference to FIGS. 1 to 8 may be omitted or simplified.

Referring to FIG. 9, the tray module 2000 according to an embodiment of the disclosure includes one or more trays 300. The tray 300 includes a non-slip material. In an embodiment, the tray 300 includes an elastomer.

For example, the tray 300 includes a thermoplastic elastomer (TPE). For example, the thermoplastic elastomer is at least one of a thermoplastic styrene block copolymer (SBC), a thermoplastic olefin elastomer (TPO), a thermoplastic polyurethane (TPU), a thermoplastic polyamide (TPAE), or a thermoplastic polyester elastomer (TPEE), etc. An olefin-based thermoplastic elastomer includes at least one of polypropylene (PP), polystyrene (PS), polyethylene (PE), nylon, styrene-acrylonitrile, ethylene propylene rubber (EPDM), natural rubber, styrene-butadiene rubber (SBR), ethylene vinyl acetate copolymer (EVA), or glycol-modified polyethylene terephthalate (PET-G), etc.

However, embodiments of the disclosure are not necessarily limited thereto. For example, in some embodiments, the tray 300 includes various elastic materials.

The tray module 2000 can accommodate a plurality of the loading target parts 1. For example, the tray module 2000 accommodates the first loading target part 1a, the second loading target part 1b, the third loading target part 1c, the fourth loading target part 1d, the fifth loading target part, and the sixth loading target part 1f.

Each of the first loading target part 1a, the second loading target part 1b, the third loading target part 1c, the fourth loading target part 1d, the fifth loading target part, and the sixth loading target part If is accommodated in the tray module 2000 and spaced apart from each other. For example, each of the first loading target part 1a, the second loading target part 1b, the third loading target part 1c, the fourth loading target part 1d, the fifth loading target part, and the sixth loading target part 1f is seated on the tray 300 and spaced apart from each other.

FIG. 9 shows that the number of the loading target parts 1 is 6, however, this is for convenience of illustration and embodiments of the disclosure are not necessarily limited thereto. For example, n pieces of the loading target parts can be accommodated in the tray module 2000. The number n is a natural number of 1 or more. Alternatively, in some embodiments, a loading target part 1 might not be accommodated in a tray module 2000. For example, when the tray module 2000 includes a plurality of multi-stacked trays 300, a loading target part 1 might not be disposed on an uppermost tray.

FIG. 9 shows that a seating surface of the loading target part 1, such as a surface in contact with the tray module 2000, is flat, however, this is for convenience of illustration and embodiments of the disclosure are not necessarily limited thereto. For example, the seating surface of the loading target part 1 is curved. For example, the loading target part 1 is a curved panel, etc.

However, embodiments of the disclosure are not necessarily limited thereto. For example, in some embodiments, the loading target part 1 is a part to be transported in a manufacturing process of a display device, a finished product, etc.

In an embodiment, the tray 300 includes a bottom portion 320, a wall portion 330, and a protruding portion 340.

The bottom portion 320 provides a surface on which the loading target part 1 can be seated. For example, the loading target part 1 is disposed on the bottom portion 320. For example, the bottom portion 320 extends in the first direction D1 and the second direction D2.

The wall portion 330 surrounds the bottom portion 120 in a plan view and extends in a direction upward from the bottom portion 320 in a cross-sectional view. Part of the wall portion 330 extends in the first direction D1 and the third direction D3. In addition, another part of the wall portion 130 extends in the second direction D2 and the third direction D3.

The protruding portion 340 protrudes from the bottom portion 320 in a direction parallel to the extension direction of the wall portion 330. For example, a level of the top surface of the wall portion 330 is coplanar with level of the top surface of the protruding portion 340.

However, embodiments of the disclosure are not necessarily limited thereto. Alternatively, in some embodiments, the tray 300 has various other shapes. For example, in an embodiment, the tray 300 does not include the protruding portion 340.

In FIG. 9, for convenience of illustration, a plurality of flow prevention patterns formed in the tray 300, such as a plurality of flow prevention patterns 324 of FIG. 10, are omitted. A detailed description of the plurality of flow prevention patterns will be described below with reference to FIG. 10 et seq.

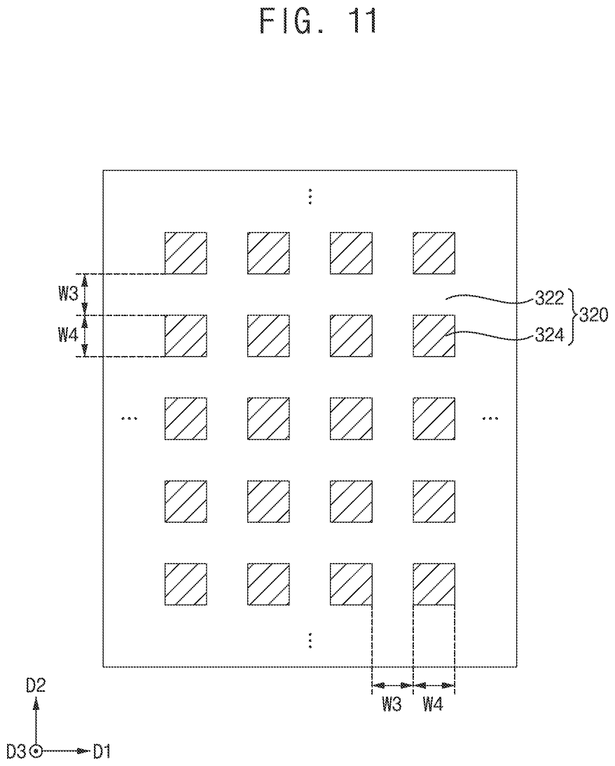

FIG. 10 is a cross-sectional view taken along the line III-III' of FIG. 9. FIG. 11 is a perspective view of a tray in the tray module of FIG. 9.

In an embodiment, the plurality of flow prevention patterns 324 protrude from the bottom portion 320 in the cross-sectional view. For example, the plurality of flow prevention patterns 324 protrude from the bottom portion 320 in the third direction D3. Each of the bottom portion 320, the plurality of flow prevention patterns 324, the wall portion 330, and the protruding portion 340 are integrally formed. However, embodiments of the disclosure are not necessarily limited thereto.

In an embodiment, the plurality of flow prevention patterns 324 have a square planar shape in a plan view. For example, the plurality of flow prevention patterns 324 have a same width W4 in the first direction D1 and the second direction D2.

In an embodiment, the tray 300 includes a top surface 322 and a bottom surface. The bottom surface faces the top surface 322. For example, the bottom surface and the top surface 322 face each other in the third direction D3.

In an embodiment, the tray 300 includes the plurality of flow prevention patterns 324. In an embodiment, each of the plurality of flow prevention patterns 324 protrudes from the bottom portion 320 of the tray 300. For example, each of the plurality of flow prevention patterns 324 protrudes from the bottom portion 320 of the tray 300 in the third direction D3.

Hereinafter, the top surface 322 of the tray 300 refers to a portion where the plurality of flow prevention patterns 324 are not formed.

In an embodiment, a distance W3 between the plurality of flow prevention patterns 324 is constant. In an embodiment, the distance W3 between the plurality of flow prevention patterns 324 is about 3 mm or more.

When the distance W3 between the plurality of flow prevention patterns 324 is less than about 3 mm, the loading target part 1 can move in the first direction D1 and/or the second direction D2 when the loading target part 1 disposed on the plurality of flow prevention patterns 324 is moved in the third direction D3. For example, when the distance W1 between the plurality of flow prevention patterns 324 is less than about 3 mm, the adhesive force is insufficient to prevent vertical and horizontal movement of the loading target part 1 in the first direction D1 and/or the second direction D2.

On the other hand, when the distance W3 between the plurality of movement prevention patterns 324 is large, the loading target part 1 can move. For example, when the distance W3 between the plurality of flow prevention patterns 324 exceeds about 5 mm, the adhesive force is insufficient to prevent vertical and/or horizontal movement of the loading target part 1.

In an embodiment, the plurality of flow prevention patterns 324 have a same width W4 as each other. In an embodiment, the width W4 of each of the plurality of flow prevention patterns 324 is greater than or equal to about 3 mm and less than or equal to about 5 mm.

When the width W4 of each of the plurality of flow prevention patterns 324 is less than about 3 mm, the loading target part 1 can move in the first direction D1 and/or the second direction D2 when the loading target part 1 disposed on the plurality of flow prevention patterns 324 moves in the third direction D3. For example, when the width W4 of each of the plurality of flow prevention patterns 324 is less than about 3 mm, the adhesive force is insufficient to prevent vertical and horizontal movement of the loading target part 1.

On the other hand, when the width W4 of each of the plurality of prevention patterns 324 is large, the loading target part 1 can move. For example, the width W4 of each of the plurality of flow prevention patterns 324 is about 5 mm or less. When the width W4 of each of the plurality of flow prevention patterns 324 exceeds about 5 mm, the adhesive force is insufficient to prevent vertical and horizontal movement of the loading target part 1.

In an embodiment, the distance W3 between the plurality of flow prevention patterns 324 and the width W4 of each of the plurality of flow prevention patterns 324 are equal to each other.

In an embodiment, a height H3 of each of the plurality of flow prevention patterns 324 is a same as each other. In an embodiment, the height H3 of each of the plurality of flow prevention patterns 324 is greater than or equal to about 0.15 mm and less than or equal to about 0.25 mm.

When the height H3 of each of the plurality of flow prevention patterns 324 is less than about 0.15 mm, the loading target part 1 can move in the first direction D1 and/or the second direction D2 when the loading target part 1 disposed on the plurality of flow prevention patterns 324 moves in the third direction D3. For example, when the height H3 of each of the plurality of flow prevention patterns 324 is less than about 3 mm, the amount of engagement is insufficient to prevent vertical and horizontal movement of the loading target part 1.

On the other hand, when the height H3 of each of the plurality of flow prevention patterns 324 exceeds about 0.25 mm, the thickness of the tray 300 increases. Accordingly, a manufacturing cost of the tray 300 increases.

The tray 300 of FIG, 10 has been described as including an elastomer and having a single-layer structure, however, this is for convenience of illustration and embodiments of the disclosure are not necessarily limited thereto. For example, in some embodiments, the tray 300 has a multi-layer structure. For example, the tray 300 includes a base portion and a pattern portion. For example, the top surface 322 of the tray 300 is a top surface of the pattern portion, and the bottom surface of the tray 300 is a bottom surface of the base portion. The base portion supports the pattern portion. The pattern portion is positioned on the base portion.

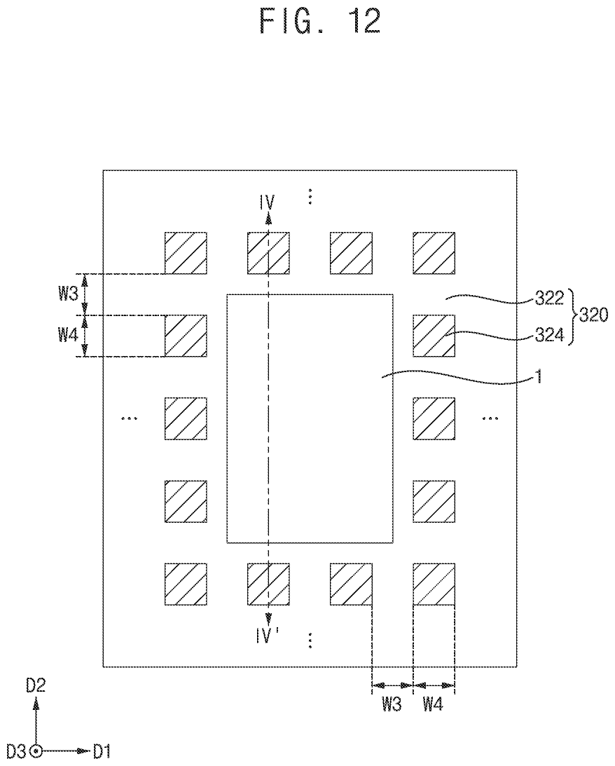

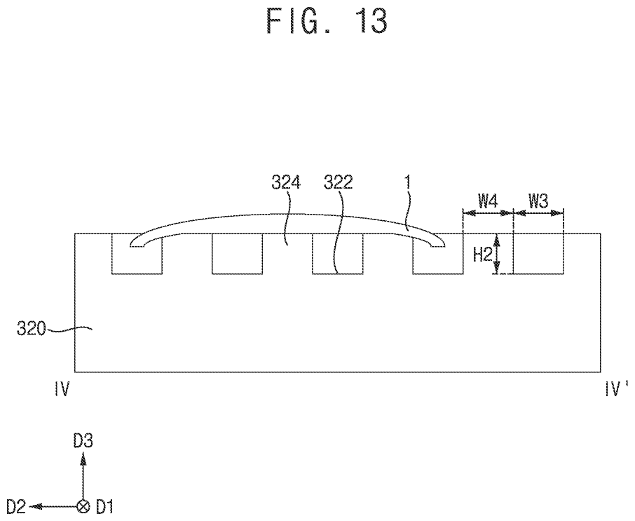

FIGS. 12 and 13 illustrate a method of transporting a loading target part by using the tray module of FIG. 9.

For example, FIG. 12 is a plan view of the tray module 2000 of FIG. 9 and the loading target part 1 accommodated in the tray module 2000. FIG. 13 is a cross-sectional view taken along line IV-IV' of FIG. 12.

Referring to FIGS. 9, 12, and 13, in an embodiment, the plurality of flow prevention patterns 324 prevent vertical and horizontal movement of the loading target part 1.

As described above, the tray 300 in the tray module 2000 includes an elastomer. The elastomer is adhesive and non-slip. Accordingly, at a position where the loading target part 1 disposed on the loading target part 1 overlaps the plurality of flow prevention patterns 324, the plurality of flow prevention patterns 324 attach to the loading target part 1. At a position where the loading target part 1 does not overlap with the plurality of flow prevention patterns 324, such as a position of the top surface 322 of the tray 300, the edge of the loading target part 1 is caught to prevent vertical and horizontal movement.

For example, the tray module 2000 does not include a pocket portion. Since the tray module 2000 does not include a pocket portion, the tray module 2000 corresponds to loading target parts 1 that have various sizes. On the other hand, since the tray module 1000 includes an elastomer, the loading target part 1 separates more easily from the tray module 2000 than when the tray module 2000 includes a high adhesive force material.

As described above, the plurality of flow prevention patterns 324 are disposed on the tray 300. The plurality of flow prevention patterns 324 have a square planar shape. The plurality of flow prevention patterns 324 have the same width W4 and are separated by a constant distance W3. Accordingly, the plurality of flow prevention patterns 324 provide an adhesive force and an amount of engagement that is sufficient to prevent vertical and horizontal movement of the loading target part 1.

In an embodiment, the distance W3 between the plurality of flow prevention patterns 324 is constant. In an embodiment, the distance W3 between the plurality of flow prevention patterns 324 is about 3 mm or more.

In an embodiment, the width W4 of each of the plurality of flow prevention patterns 324 are equal to each other. In an embodiment, the width W4 of each of the plurality of flow prevention patterns 324 are greater than or equal to about 3 mm and less than or equal to about 5 mm. In an embodiment, the plurality of flow prevention patterns 324 have the same width W4 as each other.

In an embodiment, a height H3 of each of the plurality of flow prevention patterns 324 are equal to each other. In an embodiment, the height H3 of each of the plurality of flow prevention patterns 324 is greater than or equal to about 3 mm and less than or equal to about 5 mm.

The tray module 2000 can prevent vertical and horizontal movement of the loading target part 1. When the tray module 1000 does not include a pocket portion, the loading target part 1 can move vertically and horizontally. However, the tray module 2000 according to another embodiment of the disclosure includes the plurality of flow prevention patterns 324 that prevent vertical and horizontal movement of the loading target part 1. The plurality of flow prevention patterns 324 provide an adhesive force and engagement.

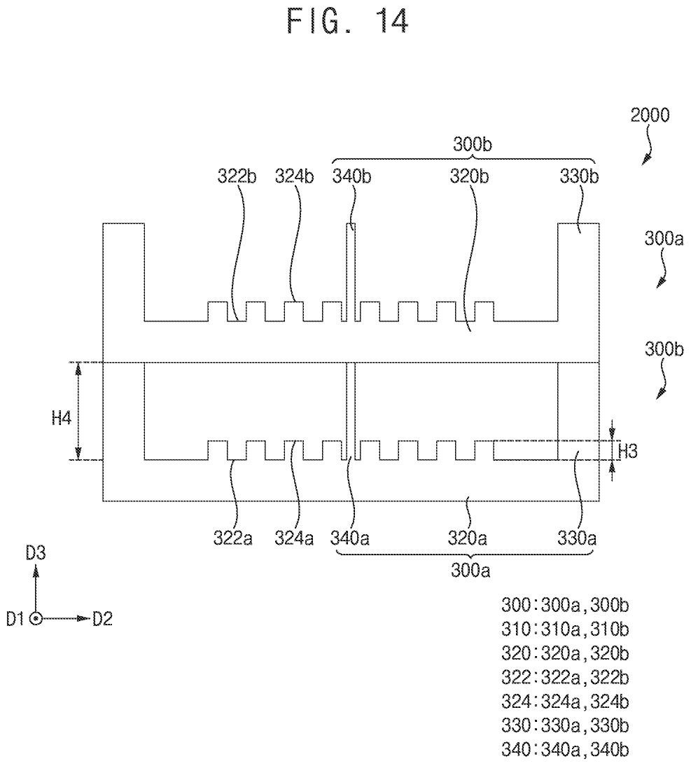

FIG. 14 illustrates a method of transporting a plurality of tray modules of FIG. 9.

Referring to FIG. 14, in an embodiment, the tray module 2000 includes at least one tray 300. For example, the tray 300 includes a first tray 300a and a second tray 300b.

In an embodiment, the tray 300 includes the bottom portion 320, the wall portion 330, and the protruding portion 340. For example, the first tray 300a includes a first bottom portion 320a, a first wall portion 330a, and a first protrusion portion 340a. The second tray 300bincludes a second bottom portion 320b, a second wall portion 330b, and a second protrusion portion 340b.

In an embodiment, the second tray 300b is disposed on the first tray 300a. For example, the first tray 100a and the second tray 100b are sequentially stacked along the third direction D3.

A level of the top surface of the wall portion 330 is coplanar a level of the top surface of the protruding portion 340. The protruding portion 340 prevents sagging of a central portion of the multi-stacked tray 300, and the wall portion 330 prevents sagging of an edge portion of the multi-stacked tray 300. In a plan view, the edge portion surrounds the central portion. For example, the second tray 300b is supported by the first wall portion 330a and the first protrusion portion 340a of the first tray 300a.

In an embodiment, the tray 300 includes the plurality of flow prevention patterns 324 that protrude from the top surface 322 of the tray 300. For example, a plurality of first flow prevention patterns 324a protrude from a top surface 322a of the first tray 300a. A plurality of second flow prevention patterns 324b protrude from a top surface 322b of the second tray 300b.

In an embodiment, a height H4 of the protrusion portion 340 differs from the height H3 of each of the plurality of flow prevention patterns 324. For example, the height H4 of the protrusion portion 340 is greater than the height H3 of each of the plurality of flow prevention patterns 324. Accordingly, even if the loading target part 1 disposed on the first tray 300a moves in the third direction D3, breakage of the loading target part 1 due to a collision can be prevented.

As described above, the tray module 2000 according to an embodiment of the disclosure includes the tray 300 that includes an elastomer. The tray 300 includes the bottom portion 320, the plurality of flow prevention patterns 324 that protrude from the bottom portion 324 in a cross-sectional view and that have a square planar shape in a plan view, and the wall portion 330 that protrudes from the bottom portion 320 in a cross-sectional view and surrounds the bottom portion 320 in a plan view. Accordingly, bidirectional flow of the loading target part 1 seated on the tray 300 can be prevented during transportation, and the loading target part 1 is easily adhered to and detached from the tray.

A tray module according to embodiments of the disclosure can be used in a process of manufacturing various electronic devices. For example, a tray module according to embodiments of the disclosure can be used in a process of manufacturing a display device included in a mobile phone, a smart phone, a video phone, a smart pad, a tablet PC, a car navigation system, a television, a computer monitor, a head mount display, etc.

Although certain embodiments and implementations have been described herein, other embodiments and modifications will be apparent from this description. Accordingly, embodiments of the inventive concepts are not necessarily limited to embodiments described herein, and various modifications and equivalent arrangements as would be apparent to a person of ordinary skill in the art are within the scope of the disclosure.

What is claimed is:

1. A tray module, comprising:
a tray; and
a pad disposed on the tray, wherein the pad has a square shape in a plan view and includes a plurality of flow prevention patterns that protrude in a cross-section view.

2. The tray module of claim 1,
wherein a distance between each of the plurality of flow prevention patterns is constant.

3. The tray module of claim 2,
wherein the distance between each of the plurality of flow prevention patterns is greater than or equal to about 3 mm and less than or equal to about 5 mm.

4. The tray module of claim 3,
wherein each of the plurality of flow prevention patterns has a same width.

5. The tray module of claim 4,
wherein the distance between each of the plurality of flow prevention patterns and the width of each of the plurality of flow prevention patterns are a same.

6. The tray module of claim 4,
wherein the width of each of the plurality of flow prevention patterns is greater than or equal to about 3 mm and less than or equal to about 5 mm.

7. The tray module of claim 1,
wherein a height of each of the plurality of flow prevention patterns are equal to each other.

8. The tray module of claim 7,
wherein the height of each of the plurality of flow prevention patterns is greater than or equal to about 0.15 mm and less than or equal to about 0.25 mm.

9. The tray module of claim 1,
wherein the tray includes a protruding portion that protrudes in a direction parallel to a protruding direction of the plurality of flow prevention patterns, and
wherein the pad further includes a hole formed at a position that corresponds to a position of the protruding portion.

10. The tray module of claim 1,
wherein the pad comprises an elastomer.

11. A tray module, comprising:
a bottom portion;
a plurality of flow prevention patterns that protrude from the bottom portion in a cross-sectional view and that have a square shape in a plan view; and
a wall portion that extends in a direction upward from the bottom portion in the cross-sectional view and surrounds the bottom portion in a plan view.

12. The tray module of claim 11,
wherein a distance between each of the plurality of flow prevention patterns is constant.

13. The tray module of claim 12,
wherein the distance between each of the plurality of flow prevention patterns is greater than or equal to about 3 mm and less than or equal to about 5 mm.

14. The tray module of claim 13,
wherein each of the plurality of flow prevention patterns has a same width.

15. The tray module of claim 14,
wherein the distance between each of the plurality of flow prevention patterns and the width of each of the plurality of flow prevention patterns are a same.

16. The tray module of claim 14,
wherein the width of each of the plurality of flow prevention patterns is greater than or equal to about 3 mm and less than or equal to about 5 mm.

17. The tray module of claim 11,
wherein a height of each of the plurality of flow prevention patterns are equal to each other.

18. The tray module of claim 17,
wherein the height of each of the plurality of flow prevention patterns is greater than or equal to about 0.15 mm and less than or equal to about 0.25 mm.

19. The tray module of claim 11,
wherein each of the bottom portion, the plurality of flow prevention patterns, and the wall portion comprises an elastomer.

20. The tray module of claim 11,
wherein each of the bottom portion, the plurality of flow prevention patterns, and the wall portion are integrally formed.
